(19) United States
(12) Patent Application Publication
(10) Pub. No.: US 2007/0054464 A1
(43) Pub. Date: Mar. 8, 2007

(54) Different STI depth for Ron improvement for LDMOS integration with submicron devices

(75) Inventor: Guowei Zhang, Singapore (SG)

Correspondence Address: ISHIMARU & ZAHRT LLP, 333 W. EL CAMINO REAL, SUITE 330, SUNNYVALE, CA, 94087, US

(73) Assignee: Chartered Semiconductor Manufacturing Ltd.

(21) Appl. No.: 11/222,482

(22) Filed: Sep. 8, 2005

(51) Int. Cl. H01L 21/76

(52) U.S. Cl. 438/424

(57) ABSTRACT

An integrated circuit device having deeper STI trenches for device isolation and shallower STI trenches at the gate edge for low on-resistance and a method for forming the same are described. The integrated circuit device of the invention comprises a gate electrode on a gate dielectric layer overlying a substrate, source and drain regions within the substrate on either side of the gate, first dielectric trenches isolating the gate electrode and source and drain regions from other devices, and a second dielectric trench underlying an edge of the gate adjacent to the drain region wherein the second dielectric trench is shallower than the first dielectric trenches.

### BACKGROUND OF THE INVENTION

(1) Field of the Invention

The invention relates to shallow trench isolation in the fabrication of integrated circuits, and more particularly, to a method of shallow trench isolation for device isolation and on-resistance improvement in the manufacture of integrated circuits.

(2) Description of the Prior Art

Integration of high voltage devices like LDMOS (Lateral Double Diffused MOSFET) with submicron low voltage devices has become important in recent years. For example, power management of single chip liquid crystal display (LCD) drivers requires high-density low voltage devices to form the memory and control circuits and high voltage devices to drive the thin film transistors (TFT) for LCD display.

Conventional LDMOS structures include a field oxidation layer underneath the edge of the polysilicon gate around the drain area to improve the breakdown voltage of the device. Breakdown is believed to occur at the silicon surface underneath the gate edge which has severe electric field crowding. The field oxide can help to distribute the potential voltage drop and to reduce electric field crowding in the silicon underneath the oxide. U.S. Pat. No. 6,316,807 (Fujishima et al) and U.S. Pat. No. 5,506,431 (Thomas) show this conventional structure. U.S. Pat. No. 6,468,870 (Kao et al) shows an electric field block over the bird's beak of a field oxide region to improve breakdown voltage. This patent teaches that the gate not be formed over a field oxide or shallow trench isolation (STI) region.

Shallow trench isolation (STI) is normally used for submicron device isolation for well-known reasons such as minimum field encroachment, better planarity, latch up immunity, low junction capacitance, and so on. When LDMOS is integrated with submicron devices, STI will be used to replace the field oxidation. However, the on-resistance (Ron) is increased significantly by deeper STI because of the extra current path underneath the STI. Ron is an important parameter, related to power loss. Low Ron is desirable for high voltage transistors.

U.S. Pat. No. 6,333,234 to Liu et al forms STI to separate high voltage MOS transistors on a silicon-on-insulator (SOI) substrate. There is a STI under one edge of the gate to isolate it from the single crystalline layer. However, no details are provided for STI formation. U.S. Pat. No. 5,683,932 to Bashir et al discloses both deep and shallow STI. A shallow STI is shown under one edge of a first gate and a deep STI is shown under the opposite edge of a second gate. The polysilicon gate is used to connect the emitter of the bipolar transistor which is a quite different function from an LDMOS gate used to provide inversion of the channel with proper bias. U.S. Pat. No. 6,787,422 to Cheong et al, assigned to a common assignee, discloses a method to form both shallow and deep trenches to form SOI MOSFET's without floating body effects. The trenches do not underlie the gates. U.S. Patent Application 2004/0251492 to Lin shows a STI on the drain side of a gate. All trenches have the same depth.

### SUMMARY OF THE INVENTION

A principal object of the present invention is to provide an effective and very manufacturable method of integrating high voltage devices with submicron devices in the fabrication of integrated circuit devices.

Another object of the invention is to provide a method of providing good isolation between devices along with low on-resistance in the integration of high voltage devices with submicron devices.

Yet another object of the invention is to provide a method of forming deeper STI trenches for device isolation and shallower STI trenches at the gate edge for low on-resistance.

In accordance with the objects of this invention a method of isolation for integrating high voltage devices with submicron devices is achieved. A polish stop layer is provided on a substrate and patterned to provide first openings where device isolation regions are to be formed. First trenches are etched into the substrate where it is exposed within the first openings. A resist layer is coated over the polish stop layer and within the first trenches and patterned to provide second openings where gate edge isolation regions are to be formed. Second trenches are etched into the silicon substrate where it is exposed within the second openings wherein the second trenches are shallower than the first trenches. The first and second trenches are filled with a dielectric layer. A source region and a drain region are formed within the substrate between two of the first trenches. A gate electrode is formed on a gate dielectric layer overlying the substrate between the source region and the drain region wherein an edge of the gate adjacent to the drain region overlies one of the second trenches.

Also in accordance with the objects of this invention, an integrated circuit device having deeper STI trenches for device isolation and shallower STI trenches at the gate edge for low on-resistance is achieved. The integrated circuit device of the invention comprises a gate electrode on a gate dielectric layer overlying a substrate, source and drain regions within the substrate on either side of the gate, first dielectric trenches isolating the gate electrode and source and drain regions from other devices, and a second dielectric trench underlying an edge of the gate adjacent to the drain region wherein the second dielectric trench is shallower than the first dielectric trenches.

### BRIEF DESCRIPTION OF THE DRAWINGS

In the accompanying drawings forming a material part of this description, there is shown:

FIGS. 1 through 6 schematically illustrate in cross-sectional representation a preferred embodiment of the present invention.

FIG. 7 schematically illustrates in cross-sectional representation an example of a completed device fabricated by the process of the present invention.

### DESCRIPTION OF THE PREFERRED EMBODIMENTS

The present invention proposes a method of improving Ron while maintaining good isolation between devices. By using different STI trench depths, using deeper STI for device isolation and shallower STI for Ron improvement, low on-resistance with good device isolation can be achieved.

Referring now more particularly to FIG. 1, there is illustrated a portion of a partially completed integrated circuit device. There is shown a substrate 10, preferably composed of monocrystalline silicon. A pad silicon dioxide layer 12 is thermally grown over the substrate surface to a thickness of between about 50 and 200 Angstroms, and preferably about 100 Angstroms. A polish stop layer 14 is deposited overlying the silicon dioxide layer 12. The polish stop layer 14 acts as a stop for the subsequent polishing of the gap fill layer. The polish stop layer 14 is preferably comprised of silicon nitride and is deposited typically by a chemical vapor deposition (CVD) process. The polish stop layer 14 is deposited to a thickness of between about 1000 and 3000 Angstroms, and preferably about 1600 Angstroms.

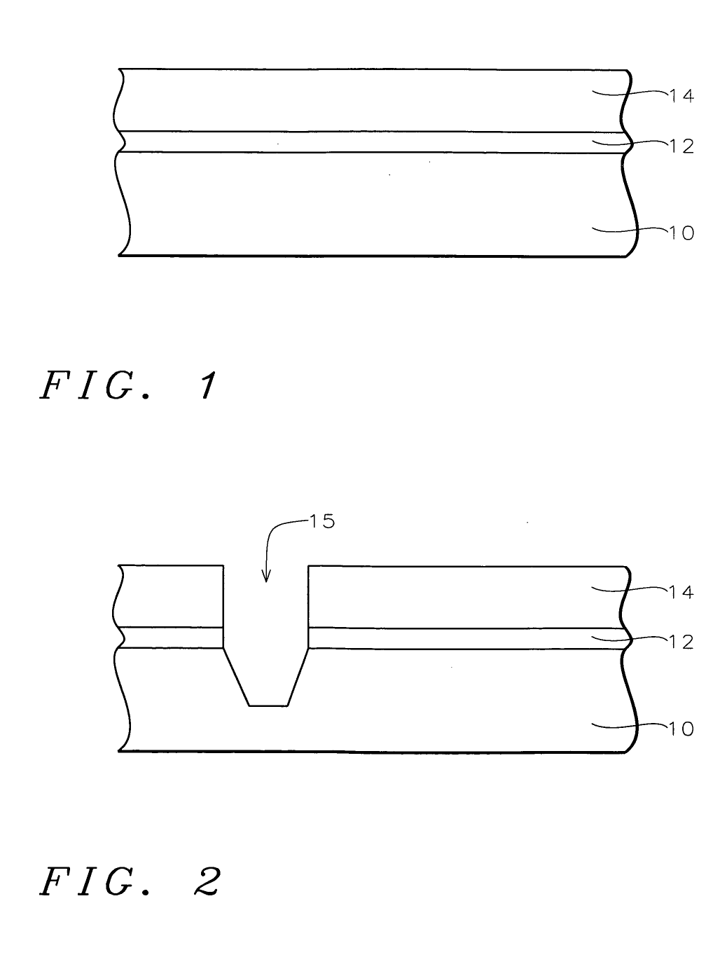

Referring now to FIG. 2, the polish stop layer 14 is patterned by masking and dry etching techniques, for example, for those areas where low voltage or high voltage device isolation trenches are to be formed. Deep trenches 15 are formed as shown. The trenches are etched using a conventional etching process such as reactive ion etching (RIE) to a depth of between about 3000 and 5000 Angstroms.

Now, shallower trenches are to be formed under the gate edge to improve on-resistance. A pattern-defining layer, such as photoresist layer 20, is formed over the polish stop layer 14 and within the trenches 15, as shown in FIG. 3. The photoresist layer is patterned to form openings where shallower trenches are to be formed. The photoresist layer protects the trenches 15 during etching of the shallower trenches. The polish stop layer 14 and the pad oxide layer 12 are etched within the openings. The silicon surface exposed in the openings is etched using a time-controlled etch to form shallower trenches 25, having a depth of between about 1000 and 3000 Angstroms. Since high voltage devices normally have a large pitch, the resolution requirement for the photoresist layer is not too high. There is a trade-off between the transistor on resistance and breakdown voltage, depending on the device application and requirements. The depth of the shallower trench can be tuned to fit the requirements.

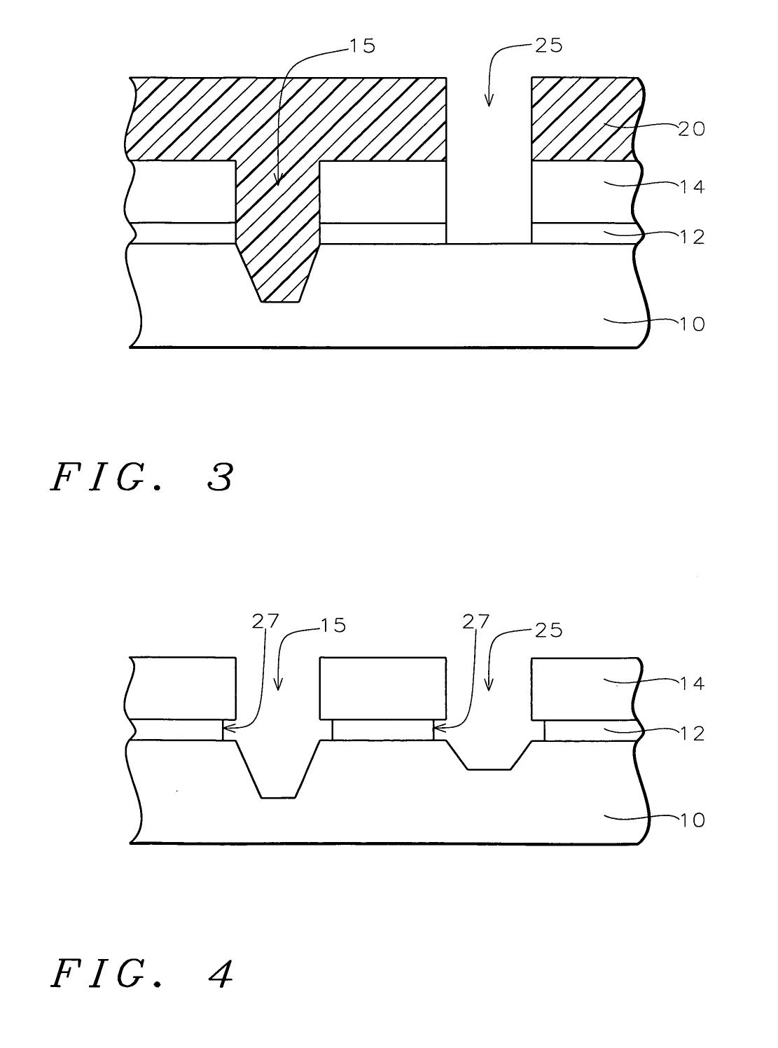

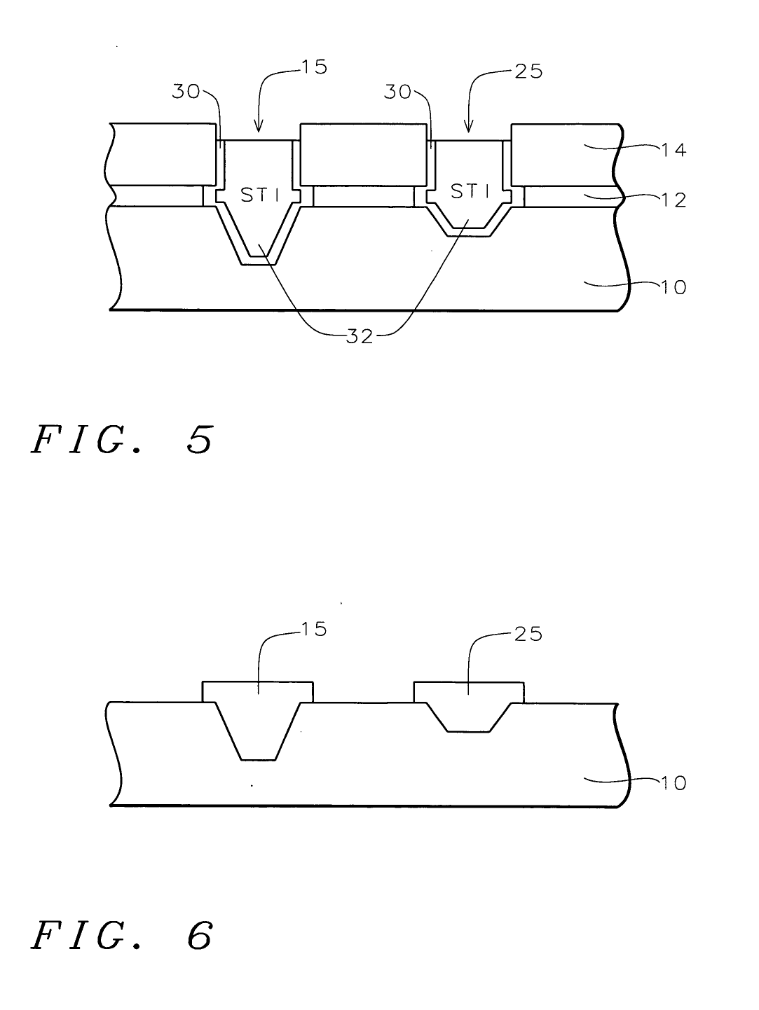

After the trenches have been etched, a dilute hydrofluoric acid (HF) dip may be performed to undercut the pad oxide, as shown by 27 in FIG. 4. The undercut is about 10 to 50 Angstroms laterally into the silicon dioxide layer 12. The sharp corner of the trench after trench etching enhances the electric field at the corner, thus degrading the transistor turn-off characteristics. To suppress this effect, the corner has to be rounded. The undercut exposes the sharp corner so that thermal oxidation can be used to round the corner, thus reducing stress.

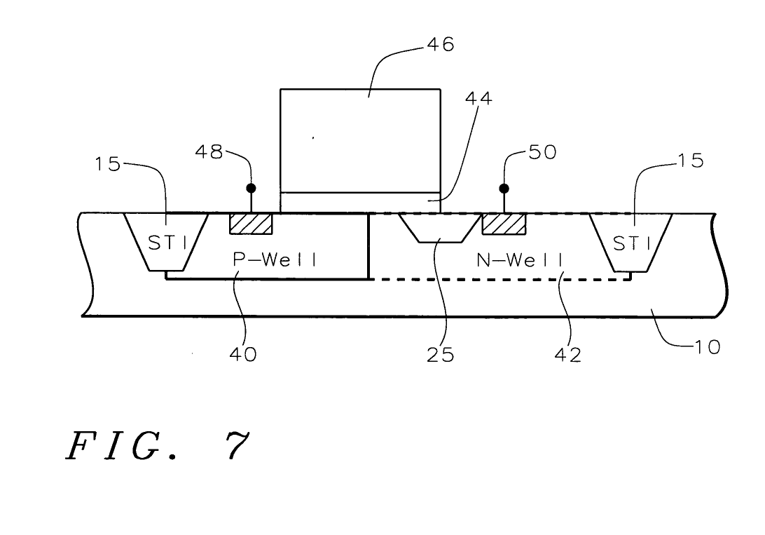

Now, a liner oxide layer 30 is grown within the trenches 15 and 25 to a thickness of between about 100 and 300 Angstroms. The liner oxide layer is not shown in subsequent figures. A dielectric layer 32 of high density plasma (HDP) undoped silicate glass (USG), for example, is deposited overlying the polish stop layer 14 and filling the trenches. Other dielectric materials may be LPCVD TEOS oxide, for example. A chemical mechanical polishing (CMP) removes the gap fill layer overlying the polish stop layer. A wet oxide and SiN removal is performed to remove a portion of the trench oxide, all of the polish stop layer, and all of the pad oxide, as shown in FIG. 6. Oxide removal is normally performed by a dilute HF dip and the SiN polish stop layer is normally removed by H₃PO₄. Approximately 400 to 1000 Angstroms of the oxide 32 is removed to improve the topology. Shallow trenches 15 and 25 remain, as shown in FIG. 6.

Processing continues as normal to fabricate the integrated circuit device. During subsequent processing, the STI regions 15 and 25 are flattened as shown in FIG. 7. For example, well formation, gate formation, source/drain formation, and back end of line (BEOL) layers are fabricated. FIG. 7 illustrates an example of a completed n-type LDMOS device. P-well 40 and N-well 42 are shown within the substrate 10. Deeper isolation trenches 15 separate the illustrated LDMOS device from other devices. Polysilicon gate electrode 46 with an underlying gate oxide layer 44 has been formed on the surface of the substrate. Source 48 and drain 50 are formed on either side of the gate. The shallower trench 25 partially underlies the drain edge of the gate 46.

The shallow trench 25 under the gate edge at the drain side improves the breakdown voltage of the device. Since the trench is shallower than a normal STI trench, electric field crowding is reduced without increasing on-resistance. Both the normal STI isolation trenches and the gate edge trench can be formed in such a manner as can be easily integrated with submicron device processing. Thus, high voltage devices such as the LDMOS illustrated in the figures can be integrated with submicron devices.

While the invention has been particularly shown and described with reference to the preferred embodiments thereof, it will be understood by those skilled in the art that various changes in form and details may be made without departing from the spirit and scope of the invention.

What is claimed is:

1. A method of isolation in the fabrication of integrated circuits comprising:
providing a polish stop layer on a substrate;
patterning said polish stop layer to provide first openings where device isolation regions are to be formed;
etching first trenches into said substrate where it is exposed within said first openings;
coating a pattern-defining layer over said polish stop layer and within said first trenches;
patterning said pattern-defining layer to provide second openings where gate edge isolation regions are to be formed;
etching second trenches into said substrate where it is exposed within said second openings wherein said second trenches are shallower than said first trenches;
filling said first and second trenches with a dielectric layer; and
removing said pattern-defining layer and said polish stop layer.

2. The method according to claim 1 further comprising providing a pad oxide layer underlying said polish stop layer.

3. The method according to claim 1 wherein said polish stop layer comprises silicon nitride.

4. The method according to claim 1 wherein said first trenches are etched to a depth of between about 3000 and 5000 Angstroms into said substrate.

5. The method according to claim 1 wherein said second trenches are etched to a depth of between about 1000 and 3000 Angstroms into said substrate.

6. The method according to claim 1 wherein said filling of said first and second trenches comprises a high density plasma (HDP) process.

7. The method according to claim 1 wherein said dielectric layer comprises undoped silica glass or TEOS oxide.

8. The method according to claim 1 further comprising forming a liner oxide layer within said first and second trenches prior to said filling said first and second trenches.

9. The method according to claim 1 further comprising:
forming a source region and a drain region within said silicon substrate between two of said first trenches; and
forming a gate electrode on a gate dielectric layer overlying said silicon substrate between said source region and said drain region wherein an edge of said gate electrode adjacent to said drain region overlies one of said second trenches.

10. The method of claim 9 wherein said second trench underlying said gate edge reduces electric field crowding, increases breakdown voltage, and decreases on-resistance.

11. The method of claim 9 wherein said gate, source, and drain comprise a high voltage device.

12. The method of claim 11 further comprising forming submicron devices in other areas of said substrate separated by said first trenches.

13. A method of isolation in the fabrication of integrated circuits comprising:
providing a polish stop layer on a substrate;
patterning said polish stop layer to provide first openings where device isolation regions are to be formed;
etching first trenches into said substrate where it is exposed within said first openings;
coating a pattern-defining layer over said polish stop layer and within said first trenches;
patterning said pattern-defining layer to provide second openings where gate edge isolation regions are to be formed;
etching second trenches into said substrate where it is exposed within said second openings wherein said second trenches are shallower than said first trenches;
filling said first and second trenches with a dielectric layer;
thereafter removing said pattern-defining layer and said polish stop layer;
forming a source region and a drain region within said silicon substrate between two of said first trenches; and
forming a gate electrode on a gate dielectric layer overlying said substrate between said source region and said drain region wherein an edge of said gate adjacent to said drain region overlies one of said second trenches.

14. The method according to claim 13 wherein said polish stop layer comprises silicon nitride.

15. The method according to claim 13 wherein said first trenches are etched to a depth of between about 3000 and 5000 Angstroms into said substrate and said second trenches are etched to a depth of between about 1000 and 3000 Angstroms into said substrate.

16. The method according to claim 13 wherein said filling of said first and second trenches comprises a high density plasma (HDP) process.

17. The method according to claim 13 wherein said dielectric layer comprises undoped silica glass or TEOS oxide.

18. The method according to claim 13 further comprising forming a liner oxide layer within said first and second trenches prior to said filling said first and second trenches.

19. The method according to claim 13 wherein said second trench underlying said gate edge reduces electric field crowding, increases breakdown voltage, and decreases on-resistance.

20. An integrated circuit device comprising:
a gate electrode on a gate dielectric layer overlying a substrate;
source and drain regions within said substrate on either side of said gate electrode;
first dielectric trenches isolating said gate electrode and said source and drain regions from other devices; and
a second dielectric trench underlying an edge of said gate electrode adjacent to said drain region wherein said second dielectric trench is shallower than said first dielectric trenches.
